(19) United States
(12) Patent Application Publication
(10) Pub. No.: US 2026/0011604 A1
(43) Pub. Date: Jan. 8, 2026

(54) METHOD FOR SEMICONDUCTOR PROCESSING

(71) Applicant: Tokyo Electron Limited, Tokyo (JP)

(72) Inventors: Ryota Yonezawa, Albany, NY (US); Kai-Hung Yu, Albany, NY (US); Gerrit Leusink, Albany, NY (US); David L. O'Meara, Albany, NY (US)

(21) Appl. No.: 18/761,411

(22) Filed: Jul. 2, 2024

(51) Int. Cl. H01L 21/768; H01J 37/32

(52) U.S. Cl. CPC H01L 21/76879; H01L 21/76802; H01L 21/76871; H01J 2237/334; H01J 37/3211

(57) ABSTRACT

A method for semiconductor manufacturing includes removing an oxide layer disposed over a conductive feature, flowing a gallium precursor over the conductive feature, and depositing a metal over the conductive feature after flowing the gallium precursor. The conductive feature is adjacent to a dielectric feature. The metal is deposited selectively over the conductive feature relative to the dielectric feature.

### TECHNICAL FIELD

The present invention relates generally to a system and method for semiconductor processing, and, in particular embodiments, to a system and method for a selective deposition process.

### BACKGROUND

Dimension shrinkage is one of the driving forces in the development of integrated circuit processing. By reducing the size dimensions, cost-benefit and device performance boosts can be obtained. This scalability creates inevitable complexity in process flow, especially on patterning techniques. For example, as smaller circuits such as transistors are manufactured, the critical dimension (CD) or resolution of patterned features is becoming more challenging to produce, particularly in high volume. Self-aligned patterning may replace overlay-driven patterning so that cost effective scaling can continue even after the introduction of extreme ultraviolet (EUV) lithography. Patterning options that enable reduced variability, extend scaling, and enhance CD and process control are useful in a high-volume manufacturing environment; however, it is getting extremely difficult to produce scaled devices at reasonably low cost and high yield. Selective deposition, together with selective etch, can significantly reduce the cost associated with advanced patterning. Selective deposition of thin films such as gap fill, area selective deposition of dielectrics and metals on specific substrates, and selective hard masks are key steps in patterning in highly scaled technology nodes.

### SUMMARY

In accordance with an embodiment, a method for semiconductor manufacturing includes: removing an oxide layer disposed over a conductive feature, the conductive feature being adjacent to a dielectric feature; flowing a gallium precursor over the conductive feature; and after flowing the gallium precursor, depositing a metal over the conductive feature, the metal being deposited selectively over the conductive feature relative to the dielectric feature.

In accordance with another embodiment, a method for semiconductor manufacturing includes: exposing a top surface of a first conductive feature with an etching process, the etching process forming an oxide layer over the top surface of the first conductive feature; removing the oxide layer by performing an atomic layer etching process; forming a gallium layer over the top surface of the first conductive feature; and forming a second conductive feature over the gallium layer with an atomic layer deposition process.

In accordance with yet another embodiment, a method for semiconductor manufacturing includes: patterning a dielectric layer over a conductive feature, the patterning forming a trench in the dielectric layer and a hole extending from the trench to a top surface of the conductive feature; performing an atomic layer etching process, the atomic layer etching process removing an oxide layer on the conductive feature; flowing a gallium precursor over the exposed top surface of the conductive feature; and filling the hole by performing a selective deposition of a first conductive material, the first conductive material being deposited selectively over the exposed top surface of the conductive feature relative to the dielectric layer.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a diagram of a processing system, in accordance with some embodiments;

FIGS. 2 through 12 illustrate cross-sectional views of intermediate steps of a selective deposition, in accordance with some embodiments;

FIGS. 13 through 19 illustrate cross-sectional views of intermediate steps of a semiconductor manufacturing process, in accordance with some embodiments;

FIG. 20 illustrates a process flow chart diagram of a method for semiconductor manufacturing, in accordance with some embodiments;

FIG. 21 illustrates a process flow chart diagram of a method for semiconductor manufacturing, in accordance with some embodiments; and

FIG. 22 illustrates a process flow chart diagram of a method for semiconductor manufacturing, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

According to one or more embodiments of the present disclosure, this application relates to semiconductor manufacturing with methods of selective deposition of metals at lower temperature. Process temperatures for conventional chemical vapor deposition (CVD) and atomic layer deposition (ALD) of, for example, tungsten using tungsten hexafluoride (WF₆) and hydrogen (H₂) reduction may be in excess of 300 ºC, which can limit usage because of thermal budget. Additionally, using tungsten hexafluoride may require a seed layer (e.g., titanium nitride (TiN)), and a pre-cleaning of metal oxide may be needed prior to deposition. As such, it is advantageous to perform a selective deposition of metal (e.g., tungsten) at a lower temperature (e.g., around 250 ºC). Metal oxide may be thermally cleaned prior to deposition by using various combinations of precursors. Embodiments include a combination of processes for thermal metal oxide cleaning and selective deposition of conductive material that may be performed at lower temperatures, thereby decreasing limitation of usage due to thermal budget.

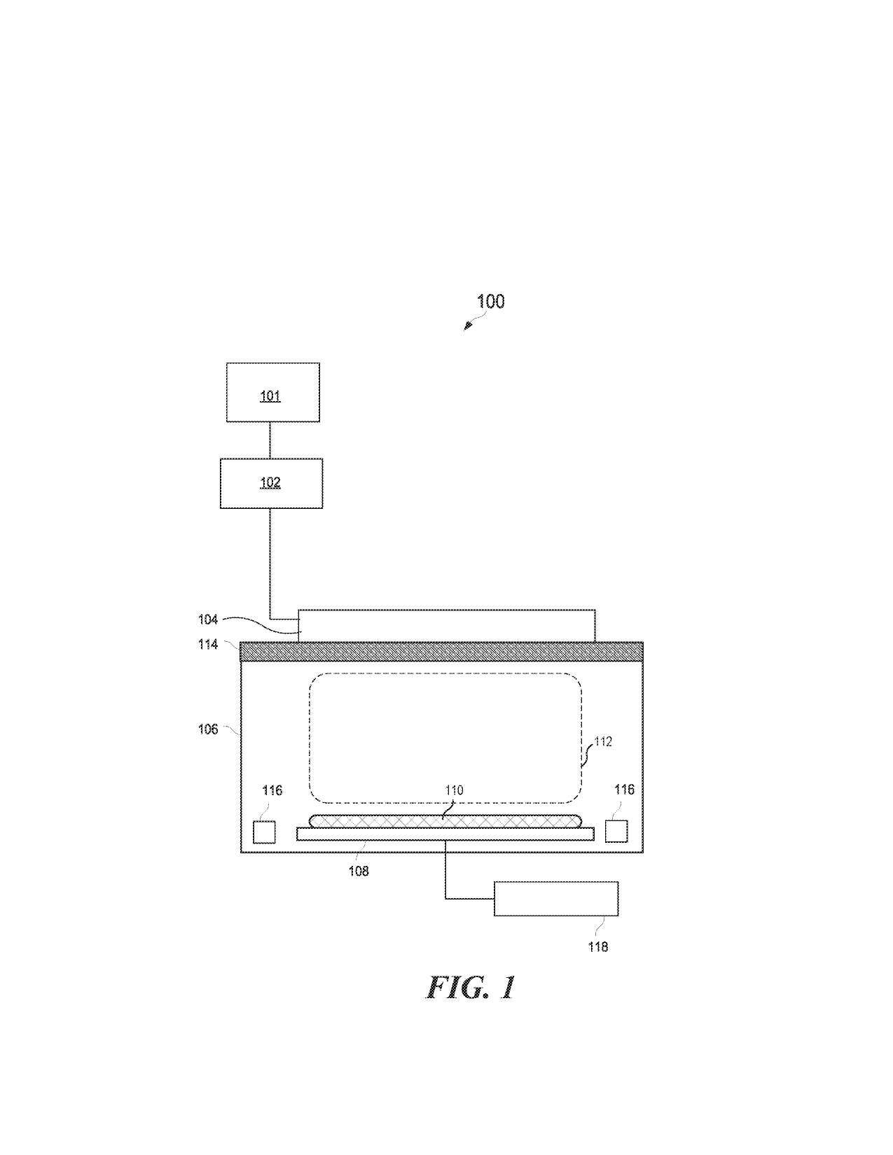

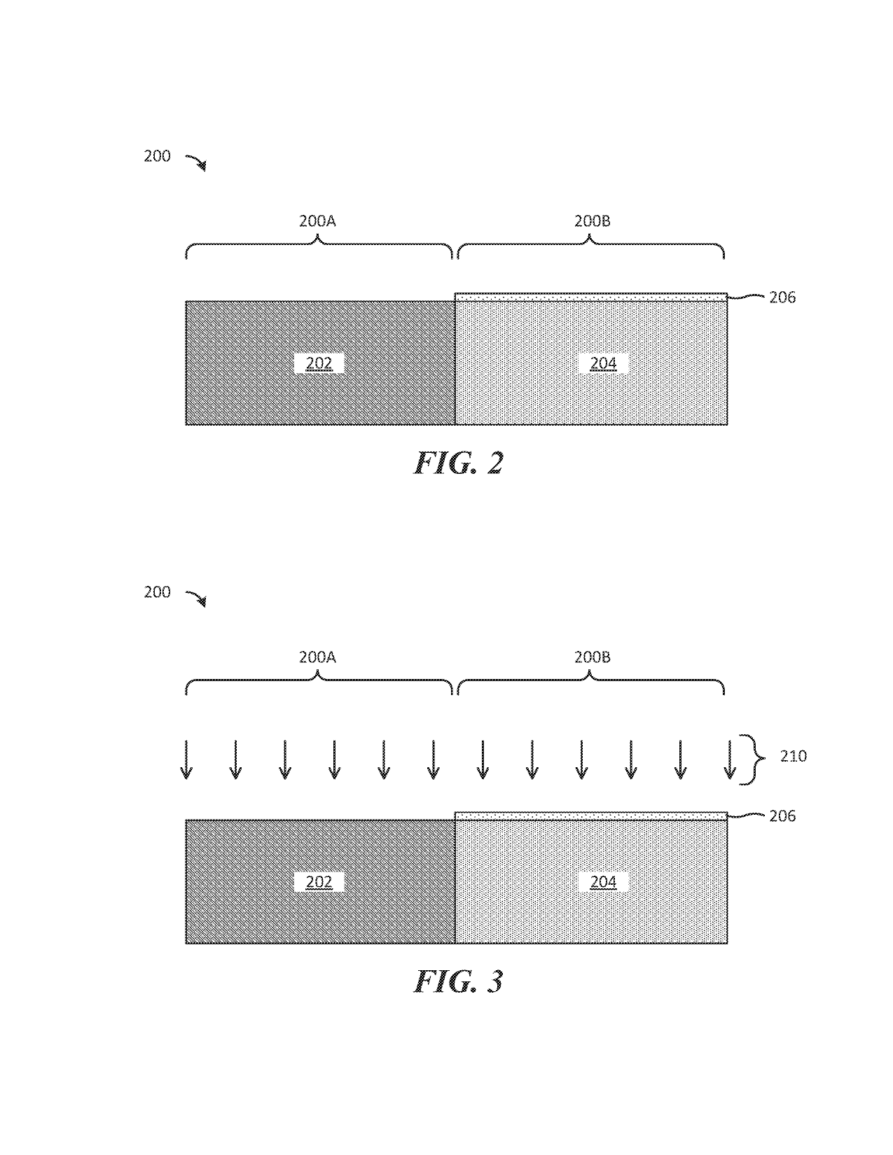

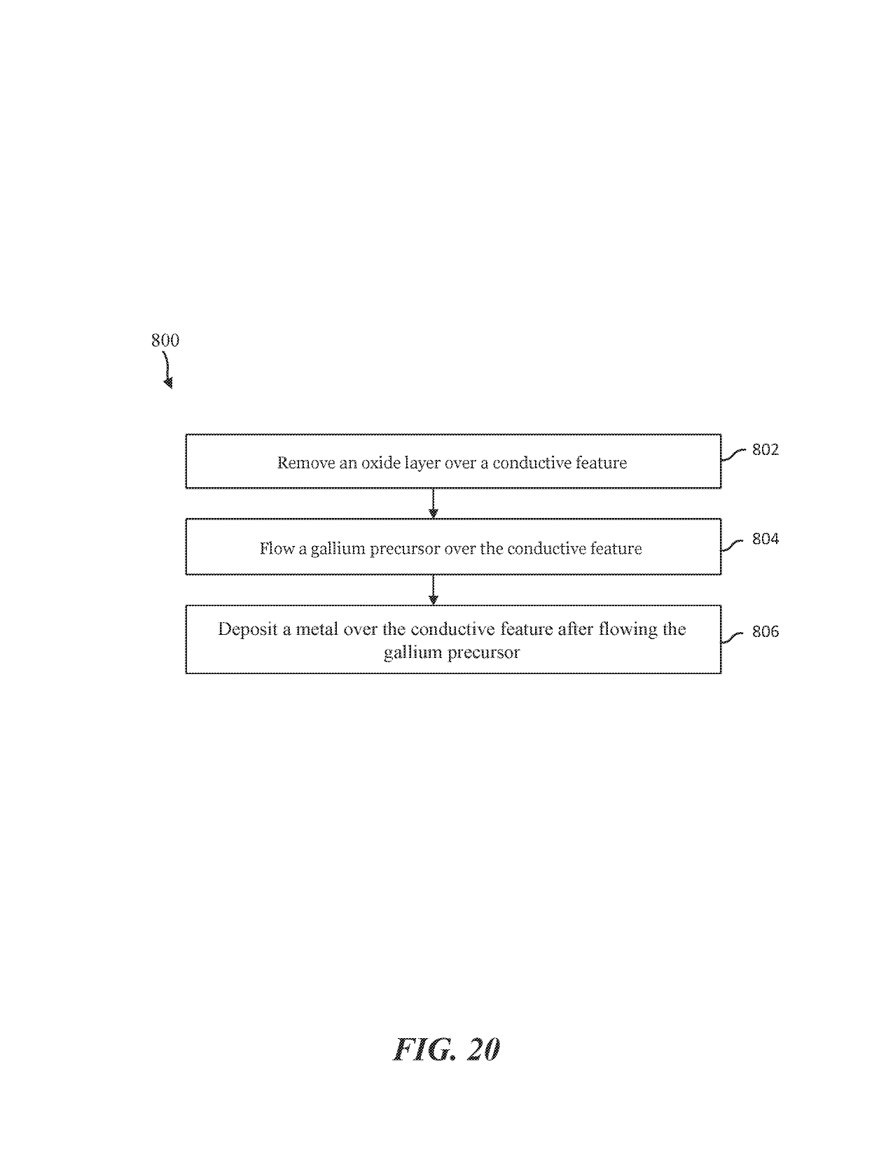

Embodiments of the disclosure are described in the context of the accompanying drawings. An embodiment of a processing system will be described using FIG. 1. An embodiment of a selective deposition process will be described using FIGS. 2-12. An embodiment of a semiconductor manufacturing process will be described using FIGS. 13-19. Embodiments of methods for semiconductor manufacturing will be described using FIGS. 20, 21, and 22.

FIG. 1 illustrates a diagram of an embodiment processing system 100, in accordance with some embodiments. As such, FIG. 1 provides one example embodiment for a processing system 100 that can be used with respect to the disclosed techniques and is provided only for illustrative purposes. The processing system 100 may be an inductively coupled plasma processing apparatus, transformer coupled plasma processing apparatus, capacitively coupled plasma processing apparatus, dual frequency capacitively coupled plasma processing apparatus, microwave plasma processing apparatus, radial line slot antenna microwave plasma processing apparatus, electron cyclotron resonance (ECR) plasma processing apparatus, or other type of processing system or combination of systems. Thus, it will be recognized by those skilled in the art that the techniques described herein may be utilized with any of a wide variety of plasma processing systems. The processing system 100 can be used for a wide variety of operations including, but not limited to, etching, deposition, cleaning, plasma polymerization, plasma-enhanced chemical vapor deposition (PECVD), atomic layer deposition (ALD), area selective deposition (ASD), plasma-enhanced area selective deposition (PEASD), and so forth. The structure of a processing system 100 is well known, and the particular structure provided herein is merely of illustrative purposes. It will be recognized that different and/or additional plasma process systems may be implemented while still taking advantage of the techniques described herein.

In the illustrated embodiment of FIG. 1, processing system 100 operates using inductively coupled plasma (ICP), in accordance with some embodiments. Processing system 100 includes an RF source 101, a matching circuit 102, an antenna 104, a process chamber 106, and, optionally, a dielectric plate 114, which may (or may not) be arranged as illustrated in FIG. 1. Further, processing system 100 may include additional components not depicted in FIG. 1.

In various embodiments, antenna 104 is coupled to an RF source 101 through a matching circuit 102. RF source 101 includes an RF power supply, which may include a generator circuit. RF source 101 provides forward RF waves to antenna 104, which are radiated towards process chamber 106. Throughout the description, the RF source 101 may be alternatively referred to as a power supply or RF source.

RF source 101 is coupled to matching circuit 102 and matching circuit 102 is coupled to antenna 104 via power transmission lines, such as coaxial cables or the like. The RF source 101 may be employed to provide RF power to the antenna 104 as a continuous wave (CW). In various embodiments, the RF source 101 may be employed to provide pulse-modulated RF power to the antenna 104.

Typically, a matching circuit (auto or manual) coupled to the radiating antenna is used to minimize losses (i.e., reflected power) in response to changes in the load condition. The matching circuit 102 (also referred to as a matching network or an impedance matching network) is coupled between the RF source 101 and the antenna 104. As forward power propagates from the RF source 101 to the antenna 104, some reflected power may be reflected back due to impedance mismatch between the process chamber 106 and the RF source 101. The matching circuit 102 is used to reduce reflected power by transforming the impedance looking into the matching circuit 102 (in other words, the impedance of the transmission lines, process chamber 106, and antenna 104) to a same impedance as the RF source 101 and any intermediate transmission lines. This increases the efficiency of supplying power to the process chamber 106.

Process chamber 106 may be, e.g., a medium frequency (MF) or high frequency (HF) plasma chamber. The process chamber 106 may be a vacuum chamber. In various embodiments, the process chamber 106 is configured to perform non-plasma processes, such as plasma-less chemical vapor deposition (CVD), atomic layer deposition (ALD), atomic layer etching (ALE), the like, or a combination thereof. In some embodiments, the process chamber 106 is configured to operate plasma 115 at a first resonant frequency, wherein the first resonant frequency is in a range from about 1 MHz to about 27 MHz. For example, the process chamber 106 may be configured to operate plasma 115 at 1 MHz or more, 13.56 MHz or more, 27 MHz or more, or the like. However, any suitable process chamber 106 may be used and may generate plasma with any suitable method, such as DC plasma, microwave plasma, transformer coupled plasma (TCP), capacitively coupled plasma (CCP), dual-frequency capacitively coupled plasma (CCP), the like, or a combination thereof.

In various embodiments, process chamber 106 includes a substrate holder 108 (e.g., a chuck). As illustrated, substrate 110 (e.g., a semiconductor wafer) is placed on substrate holder 108 to be processed. Optionally, process chamber 106 may include a bias power supply 118 coupled to substrate holder 108. The process chamber 106 may also include one or more pump outlets 116 to remove by-products from process chamber 106 through selective control of gas flow rates within. In various embodiments, pump outlets 116 are placed near (e.g., below/around the perimeter of) substrate holder 108 and substrate 110. In various embodiments, process chamber 106 may include additional substrate holders (not illustrated). In various embodiments, the placement of the substrate holder 108 may differ from that illustrated in FIG. 1. Thus, the quantity and position of the substrate holder 108 are non-limiting.

In various embodiments, antenna 104 radiates an electromagnetic field toward the process chamber 106. In an embodiment, antenna 104 includes arms connected to capacitive structures that generate the azimuthal symmetry. In various embodiments, the excitation frequency of the antenna 104 is in the radio frequency range (10-400 MHz), which is not limiting, and other frequency ranges can similarly be contemplated. For example, inventive aspects disclosed herein equally apply to applications in the microwave frequency range. Various examples of designs for antennas 104 may be found in U.S. Patent Application No. 17,649,823, which is incorporated by reference herein in its entirety. However, any suitable antenna 104 may be used.

In various embodiments, antenna 104 is outside of process chamber 106 and is separated from process chamber 106 by the dielectric plate 114, which is typically made of a dielectric material. Dielectric plate 114 separates the low-pressure environment within process chamber 106 from the external atmosphere. It should be appreciated that antenna 104 can be placed directly adjacent to dielectric plate 114. In various embodiments, antenna 104 is separated from process chamber 106 by air. In various embodiments, the properties of the dielectric plate 114 are selected to minimize reflections of the RF wave from the process chamber 106. In other embodiments, antenna 104 is embedded within the dielectric plate 114. In various embodiments, dielectric plate 114 is in the shape of a disk. The dielectric plate 114 may be transparent or semitransparent to light, such as laser light produced by the laser generator 120.

The dielectric plate 114 includes a first outer surface and a second outer surface. The first outer surface faces the process chamber 106. The second outer surface faces the antenna 104. The second outer surface is above the first outer surface in a vertical direction.

In an embodiment, the antenna 104 couples RF power from RF source 101 to the process chamber 106 to treat substrate 110. In particular, antenna 104 radiates an electromagnetic wave in response to being fed the forward RF waves from RF source 101. The radiated electromagnetic wave penetrates from the atmospheric side (i.e., antenna 104 side) of the dielectric plate 114 into process chamber 106. The radiated electromagnetic wave generates an electromagnetic field within the process chamber 106. The generated electromagnetic field ignites and sustains plasma in a plasma generating region 112 by transferring energy to free electrons within the process chamber 106. The generated plasma can be used for a plasma process to, for example, selectively etch or deposit material on substrate 110. The plasma process may include an etch process such as a Reactive Ion Etch (RIE) process, an Atomic Layer Etch (ALE) process or the like, a deposition process such as an Area Selective Deposition (ASD) process, a Plasma-Enhanced Physical Vapor Deposition (PVD) process, a Plasma-Enhanced Chemical Vapor Deposition (CVD) process, an Atomic Layer Deposition (ALD) process, or the like.

In various embodiments, the plasma generating region 112 is immediately below the nearest portion of the dielectric plate 114 to the process chamber 106. In various embodiments, the upper most surface of the plasma generating region 112 corresponds to the plane where the outer surface of the dielectric plate 114 faces the process chamber 106.

In FIG. 1, antenna 104 is external to process chamber 106. In various embodiments, however, antenna 104 can be placed internal to the process chamber 106. In such an embodiment, the plasma generating region 112 is immediately below the nearest portion of the antenna 104 to the process chamber 106.

FIGS. 2-12 illustrate cross-sectional views of a semiconductor structure 200 (also referred to as a substrate) at intermediate stages of a selective deposition process, in accordance with some embodiments. In FIG. 2, a semiconductor structure 200 comprises a first layer 202 in a first region 200A and a second layer 204 in a second region 200B adjacent to the first region 200A. The semiconductor structure 200 may be at any suitable stage of the semiconductor manufacturing process. For example, the semiconductor structure 200 may be at an intermediate stage of a front end of the line (FEOL) process, a middle end of the line (MEOL) process, a back end of the line (BEOL) process, or the like. The semiconductor structure 200 may be provided into a process chamber (e.g., the process chamber 106; see above, FIG. 1) in the intermediate stage illustrated by FIG. 2, or in a stage prior to the intermediate stage illustrated by FIG. 2.

The first layer 202 and the second layer 204 may be any suitable layers, such as adjacent areas of dielectric and conductive materials on a wafer prior to manufacturing of a transistor, adjacent metal and dielectric areas of an interconnect structure, or the like. Although FIG. 2 illustrates the first layer 202 and the second layer 204 as having co-planar top surfaces, the top surfaces of the first layer 202 and the second layer 204 may be uneven. For example, the top surface of the first layer 202 may be higher than the adjacent top surface of the second layer 204, such that a sidewall of the first layer 202 is exposed above the top surface of the second layer 204.

The first layer 202 comprises a first material and the second layer 204 comprises a second material different from the first material. In various embodiments, the first layer 202 comprises a dielectric material (e.g., silicon oxide; silicon nitride; aluminum oxide; a Group IVB transition metal oxide such as hafnium oxide, zirconium oxide, the like, or a combination thereof such as hafnium zirconium oxide; a low-k dielectric such as organosilicate glass (SiCOH); the like; or a combination thereof) and the second layer 204 comprises a conductive material such as a metal. In some embodiments, the first layer 202 comprises silicon oxide (SiO), silicon dioxide (SiO₂), or a combination thereof formed with direct liquid injection (DLI) or another suitable technique. In some embodiments the second layer 204 comprises tungsten (W), ruthenium (Ru), copper (Cu), tin (Sn), titanium (Ti), hafnium (Hf), silver (Ag), gold (Au), cobalt (Co), nickel (Ni), molybdenum (Mb), niobium (Nb), tantalum (Ta), rhodium (Rh), iridium (Ir), palladium (Pd), indium (In), zinc (Zn), antimony (Sb), the like, or a combination thereof.

In various embodiments, an oxide layer 206 is disposed over the second layer 204. The oxide layer 206 may be a metal oxide layer formed thermally from the underlying metal of the second layer 204. In some embodiments, the oxide layer 206 is a tungsten oxide layer formed by a prior process to remove material from above the second layer 204. For example, an etch process (such as a reactive ion etch or the like) may be used to remove dielectric material of the first layer 202 and uncover the second layer 204, creating a thermal metal oxide over the second layer 204 in the process.

FIGS. 3 through 6 illustrate an atomic layer etching (ALE) process to remove the oxide layer 206, in accordance with some embodiments. The ALE process may be performed with similar steps and precursors as a subsequent atomic layer deposition (ALD) process but at a lower temperature in order to achieve etching of the oxide layer 206 rather than deposition of a conductive material. In FIG. 3, a first precursor gas 210 is flowed over the semiconductor structure 200. In various embodiments, the first precursor gas 210 comprises a metal such as tungsten. For example, the first precursor gas 210 may be a tungsten precursor comprising tungsten pentachloride (WCl₅), tungsten hexachloride (WCl₆), tungsten hexafluoride (WF₆), tungsten hexacarbonyl (W(CO)₆), the like, or a combination thereof. In some embodiments, the first precursor gas 210 is flowed at a flow rate in a range of 10 sccm to 1000 sccm, under a pressure in a range of 10 mTorr to 10000 mTorr, and for a duration of 10 seconds to 2000 seconds. In some embodiments, the first precursor gas 210 is flowed at a temperature in a range of 100 ºC to 300 ºC.

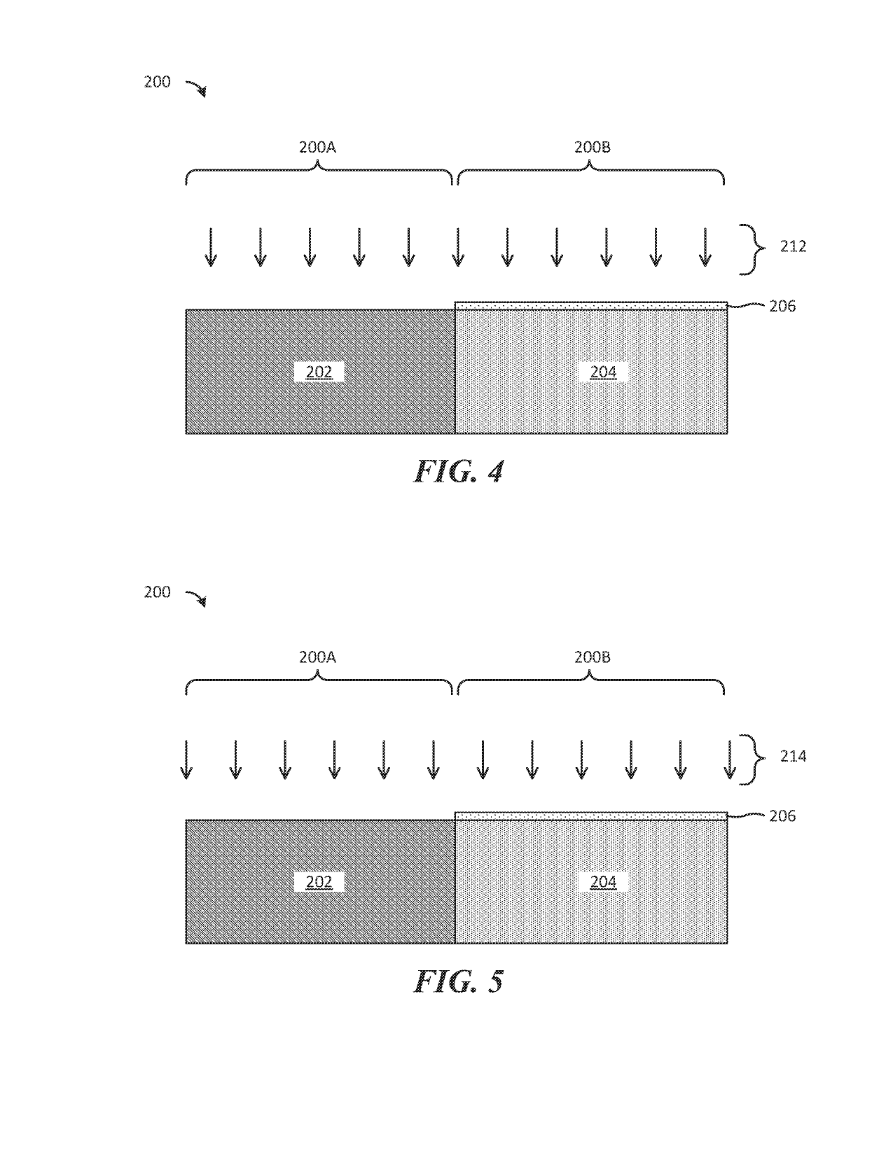

Next, in FIG. 4, a first purge 212 is performed to clear the process chamber (e.g., a process chamber 106; see above, FIG. 1) of the first precursor gas 210. In various embodiments, the first purge 212 is performed with an inert gas such as argon (Ar), nitrogen (N₂), helium (He), the like, or a combination thereof. In some embodiments, the first purge 212 is performed by flowing the inert gas at a flow rate in a range of 100 sccm to 4000 sccm, under a pressure in a range of 10 mTorr to 10000 mTorr, and for a duration of 10 seconds to 2000 seconds. In some embodiments, the first purge 212 is performed at a temperature in a range of 100 ºC to 300 ºC.

In FIG. 5, following from FIG. 4, a second precursor gas 214 is flowed over the semiconductor structure 200. In various embodiments, the second precursor gas 214 comprises boron. For example, the second precursor gas 214 may be a boron precursor comprising boron trifluoride (BF₃), boron trichloride (BCl₃), diborane (B₂H₆), the like, or a combination thereof. In some embodiments, the second precursor gas 214 is flowed at a flow rate in a range of 10 sccm to 1000 sccm, under a pressure in a range of 10 mTorr to 10000 mTorr, and for a duration of 10 seconds to 2000 seconds. In some embodiments, the second precursor gas 214 is flowed at a temperature in a range of 100 ºC to 300 ºC.

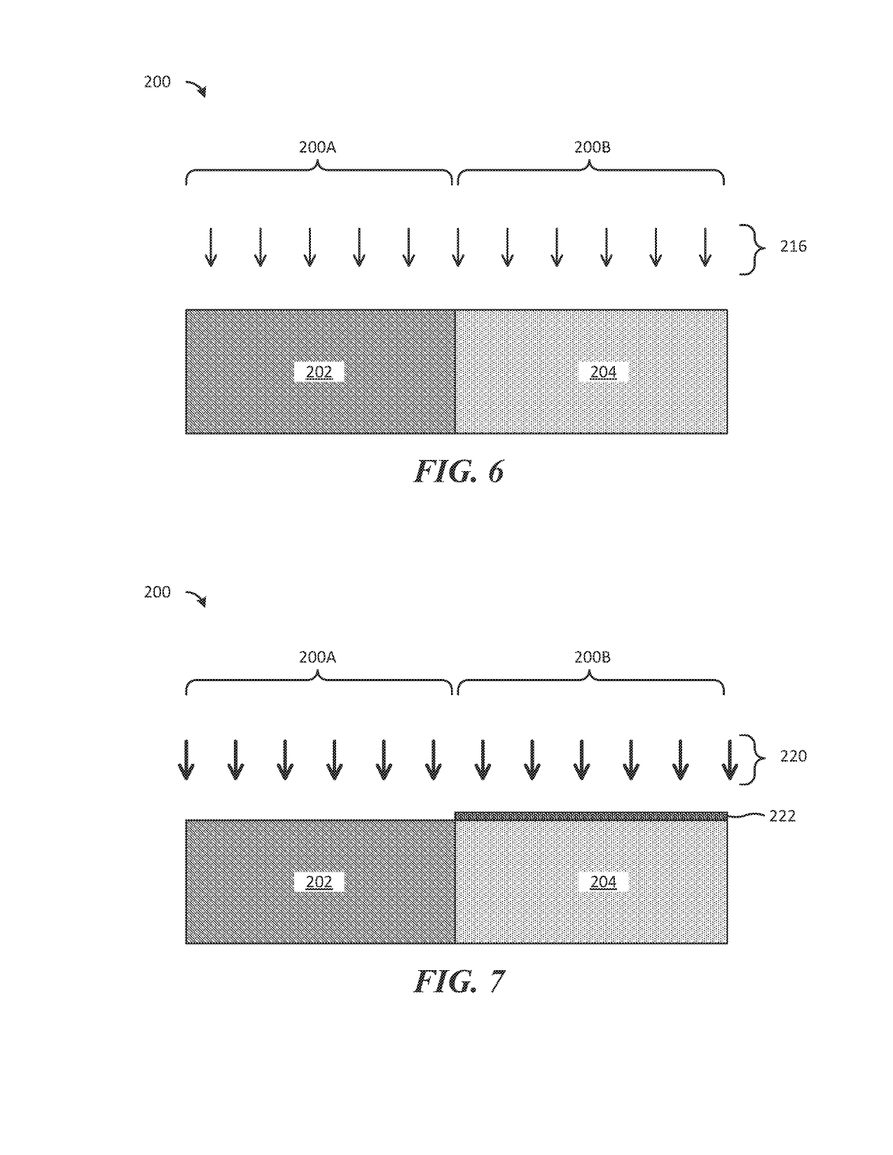

Next, in FIG. 6, a second purge 216 is performed to clear the process chamber (e.g., a process chamber 106; see above, FIG. 1) of the second precursor gas 214. In various embodiments, the second purge 216 is performed using similar methods and gases as the first purge 212 as described above with respect to FIG. 4, and the details are not repeated herein. The steps of flowing the first precursor gas 210, performing the first purge 212, flowing the second precursor gas 214, and performing the second purge 216 as illustrated by FIGS. 3-6 may be performed for any suitable number of cycles, such as 1 to 200 cycles, until the oxide layer 206 is sufficiently removed from the second layer 204.

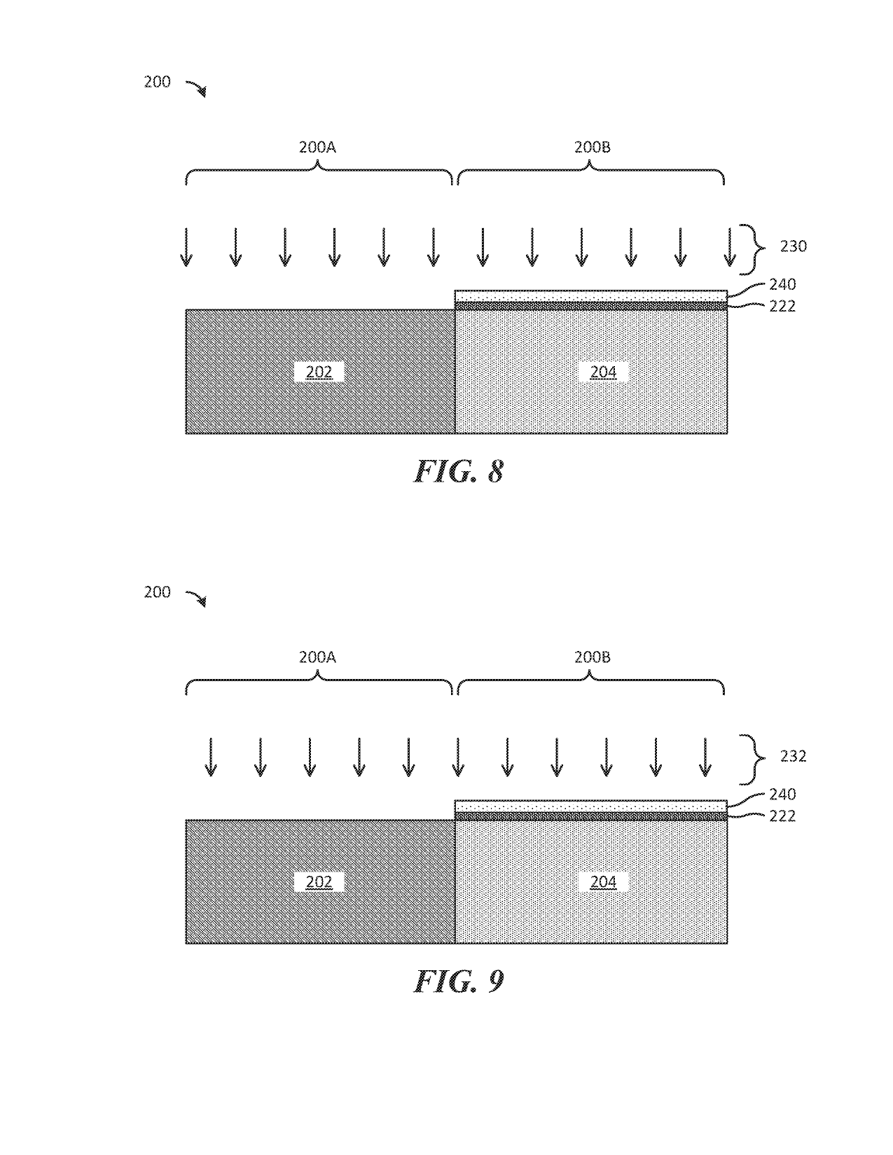

In FIG. 7, a gallium layer 222 is formed over the second layer 204 by flowing a gallium precursor 220, in accordance with some embodiments. The presence of the gallium layer 222 may promote the subsequent selective deposition of a conductive layer over the second layer 204 with, for example, an atomic layer deposition process (see below, FIGS. 8-11). Although the gallium layer 222 is referred to as a layer, the gallium layer 222 may have a thickness of less than 5 nm, such as a monolayer of gallium. In some embodiments, the gallium layer 222 covers some portions of the second layer 204 while leaving other portions of the second layer 204 uncovered.

Experimental evidence has suggested that the addition of gallium may assist the selective deposition of conductive materials such as tungsten in an atomic layer deposition process. During a coupon test in which a coupon was adhered to a substrate with a gallium-indium paste, a contamination of gallium chloride was observed to selectively deposit on metal areas of the substrate more than on silicon dioxide (SiO₂) areas of the substrate. The gallium of the gallium chloride came from the gallium-indium paste. Unexpected results occurred when the gallium chloride on the metal areas further reacted with tungsten hexafluoride (WF₆) and boron trichloride (BCl₃) to form tungsten over the metal areas of the substrate. As such, the presence of gallium, originated from contamination from the gallium-indium paste, helped to increase the efficiency of a selective deposition of tungsten on the metal areas of the substrate more than on the silicon dioxide (SiO₂) areas of the substrate. Elemental analysis of experimental results confirmed that little or no oxygen was present at the interface of the deposited tungsten with neighboring features and only a minimum amount of chlorine and fluorine were present in the bulk tungsten layer when the tungsten was formed in the presence of gallium.

In various embodiments, the gallium precursor 220 comprises gallium(II) chloride (Ga₂Cl₄), gallium trichloride (GaCl₃), gallium(III) iodide (GaI₃), gallium(III) bromide (GaBr₃), gallium(III) fluoride (GaF₃), the like, or a combination thereof. In some embodiments, the gallium precursor 220 is flowed at a flow rate in a range of 10 sccm to 1000 sccm, under a pressure in a range of 10 mTorr to 10000 mTorr, and for a duration of 10 seconds to 2000 seconds. In some embodiments, the second precursor gas 214 is flowed at a temperature in a range of 100 ºC to 300 ºC.

In some embodiments, a purge is performed to clear the process chamber (e.g., a process chamber 106; see above, FIG. 1) of the gallium precursor 220. In various embodiments, the purge of the gallium precursor 220 is performed using similar methods and gases as the first purge 212 as described above with respect to FIG. 4, and the details are not repeated herein.

FIGS. 8 through 12 illustrate an atomic layer deposition (ALD) process to deposit a conductive material that is selective to the second layer 204 over the first layer 202, in accordance with some embodiments. The ALD process may be performed with similar steps and precursors as the atomic layer etching (ALE) process described above with respect to FIGS. 3-6 but at a higher temperature in order to achieve selective deposition of the conductive material rather than etching. The presence of the gallium layer 222 over the second layer 204 may be advantageous by increasing the efficiency of the ALD process.

In FIG. 8, a first precursor gas 230 is flowed over the semiconductor structure 200. In various embodiments, the first precursor gas 230 comprises a metal such as tungsten. The first precursor gas 230 may comprise one or more of the same compounds listed above for the first precursor gas 210 with respect to FIG. 3, and the details are not repeated herein. The first precursor gas 230 forms an adsorbed layer 240 over the second layer 204 and the gallium layer 222, which may increase the efficiency of the formation of the adsorbed layer 240. In some embodiments, the adsorbed layer 240 comprises tungsten.

In some embodiments, the first precursor gas 210 is flowed at a flow rate in a range of 10 sccm to 1000 sccm, under a pressure in a range of 10 mTorr to 10000 mTorr, and for a duration of 10 seconds to 2000 seconds. In some embodiments, the first precursor gas 210 is flowed at a temperature in a range of 100 ºC to 300 ºC, or in a range of 225 ºC to 275 ºC, such as around 250 ºC.

Next, in FIG. 9, a first purge 232 is performed to clear the process chamber (e.g., a process chamber 106; see above, FIG. 1) of the first precursor gas 230. In various embodiments, the first purge 232 is performed using similar methods and gases as the first purge 212 as described above with respect to FIG. 4, and the details are not repeated herein. In some embodiments, the first purge 232 is performed by flowing an inert gas at a flow rate in a range of 100 sccm to 4000 sccm, under a pressure in a range of 10 mTorr to 10000 mTorr, and for a duration of 10 seconds to 2000 seconds. In some embodiments, the first purge 212 is performed at a in a range of 100 ºC to 300 ºC, or in a range of 225 ºC to 275 ºC, such as around 250 ºC.

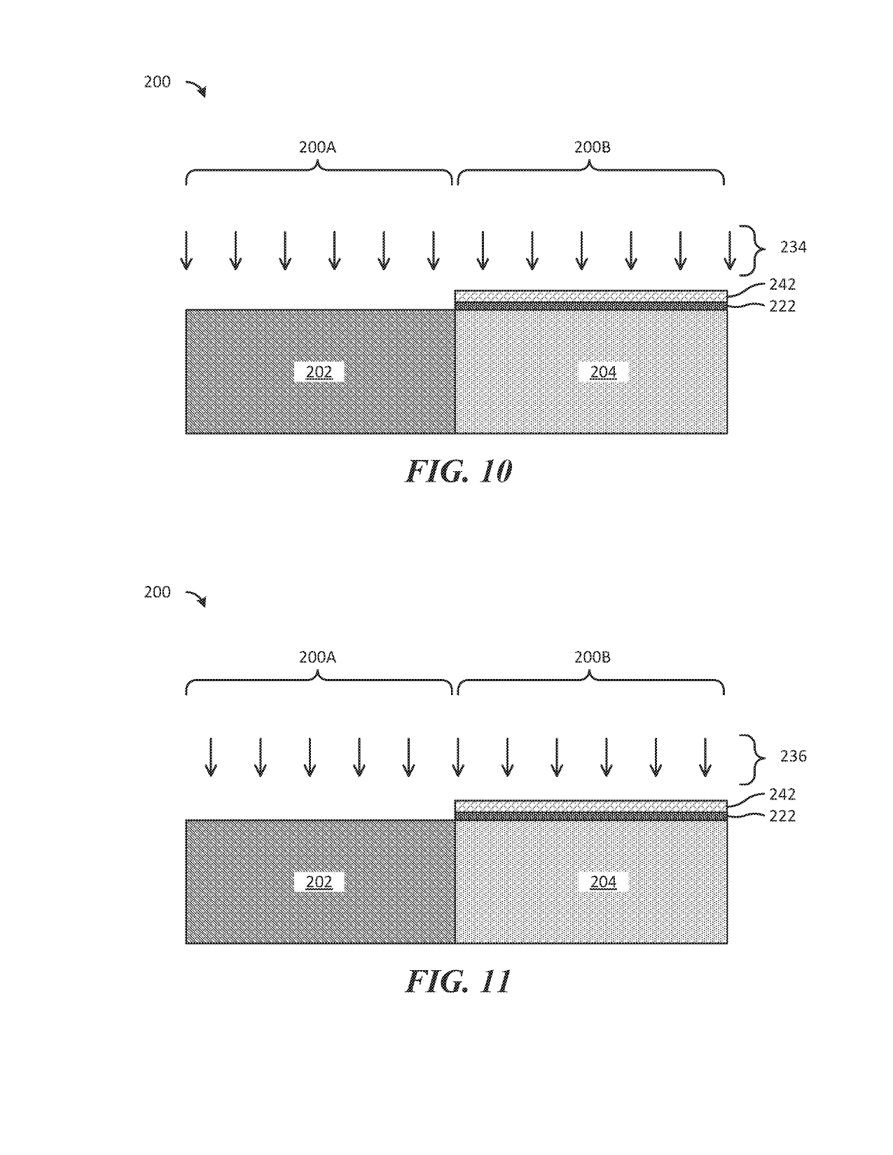

In FIG. 10, following from FIG. 9, a second precursor gas 234 is flowed over the semiconductor structure 200. In various embodiments, the second precursor gas 234 comprises one or more of the same compounds listed above for the second precursor gas 214 as described above with respect to FIG. 5, and the details are not repeated herein. The second precursor gas 234 reacts with the adsorbed layer 240 (see above, FIGS. 8-9) to form a conductive layer 242. In various embodiments, the conductive layer 242 comprises tungsten.

In some embodiments, the second precursor gas 234 is flowed at a flow rate in a range of 10 sccm to 1000 sccm, under a pressure in a range of 10 mTorr to 10000 mTorr, and for a duration of 10 seconds to 2000 seconds. In some embodiments, the second precursor gas 234 is flowed at a temperature in a range of 100 ºC to 300 ºC, or in a range of 225 ºC to 275 ºC, such as around 250 ºC.

Next, in FIG. 11, a second purge 236 is performed to clear the process chamber (e.g., a process chamber 106; see above, FIG. 1) of the second precursor gas 234. In various embodiments, the second purge 236 is performed using similar methods and gases as the first purge 212 as described above with respect to FIG. 4, and the details are not repeated herein. In some embodiments, the second purge 236 is performed by flowing an inert gas at a flow rate in a range of 100 sccm to 4000 sccm, under a pressure in a range of 10 mTorr to 10000 mTorr, and for a duration of 10 seconds to 2000 seconds. In some embodiments, the second purge 236 is performed at a in a range of 100 ºC to 300 ºC, or in a range of 225 ºC to 275 ºC, such as around 250 ºC.

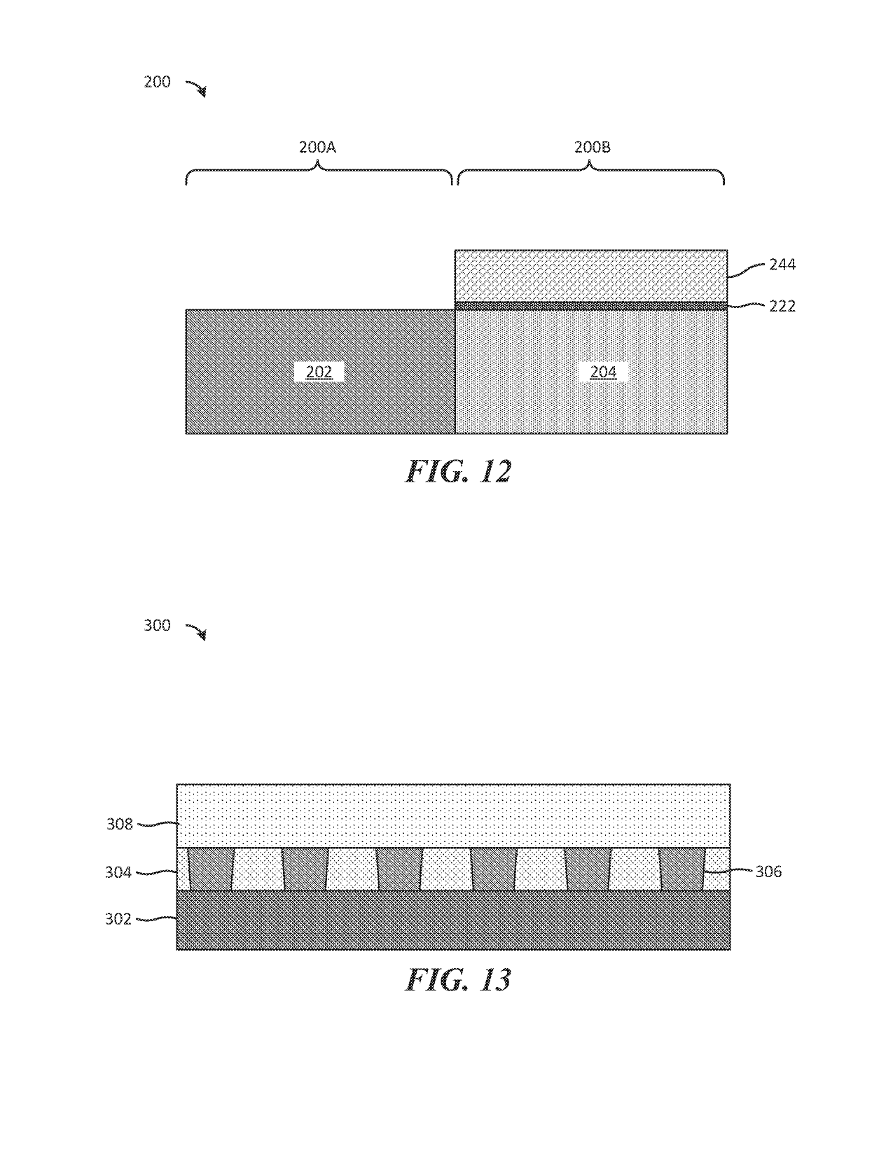

FIG. 12, following from FIG. 11, illustrates a conductive layer 244 formed over the second layer 204, in accordance with some embodiments. The conductive layer 244 is formed by successively forming conductive layers 242 (see above, FIGS. 10-11) until a desired thickness of conductive material is deposited. The steps of flowing the first precursor gas 230, performing the first purge 232, flowing the second precursor gas 234, and performing the second purge 236 as illustrated by FIGS. 8-11 may be performed for any suitable number of cycles, such as 1 to 200 cycles, to form the conductive layer 244 to a desired thickness.

In some embodiments, the steps of FIGS. 2-12 are performed in situ in a same process chamber, such as the process chamber 106 (see above, FIG. 1). However, each of the steps of FIGS. 2-12 may also be performed in two or more different process chambers.

FIGS. 13 through 19 illustrate cross-sectional views of a semiconductor structure 300 (also referred to as a substrate) at intermediate stages of a semiconductor manufacturing process, in accordance with some embodiments. In FIG. 13, a semiconductor structure 300 is provided into a process chamber (e.g., a process chamber 106; see above, FIG. 1). The semiconductor structure 300 includes a substrate 302, a first dielectric layer 304 over the substrate 302, conductive features 306 disposed in the first dielectric layer 304, and a second dielectric layer 308 over the first dielectric layer 304 and the conductive features 306.

The substrate 302 may be a silicon wafer, such as a wafer having a diameter in a range of 100 mm to 500 mm, such as a diameter of 150 mm, 200 mm, 300 mm, or 450 mm. In various embodiments, the substrate 302 may be a part of, or include, a semiconductor device, and may have undergone a number of steps of processing following, for example, a conventional process. The substrate 302 accordingly may comprise layers of semiconductors useful in various microelectronics, such as various device regions.

In one or more embodiments, the substrate 302 may be a silicon wafer, or a silicon-on-insulator (SOI) wafer. In certain embodiments, the substrate 302 may comprise silicon germanium, silicon carbide, gallium arsenide, gallium nitride, or other compound semiconductors. In other embodiments, the substrate 302 comprises heterogeneous layers such as silicon germanium on silicon, gallium nitride on silicon, silicon carbon on silicon, as well layers of silicon on a silicon or SOI substrate. In various embodiments, the substrate 302 is patterned or embedded in other components of the semiconductor device. In some embodiments, the substrate 302 comprises conductive features (e.g., metal lines, not illustrated) embedded therein. The conductive features may be electrically coupled to active devices (not illustrated) further embedded in the substrate 302.

The first dielectric layer 304 is over the substrate 302. In various embodiments, the first dielectric layer 304 comprises one or more insulators such as silicon dioxide (SiO₂) or a silicon oxide based low-k dielectric (e.g., porous oxides, fluorosilicate glass (FSG), and organosilicate glass (OSG)). In some embodiments, the first dielectric layer 304 includes a bottom layer that is an etch stop layer (ESL) that comprises a dielectric such as Si₃N₄, SiOₓN_{y}, SiC, or SiCN (not shown). Conductive features 306 (e.g., metal vias and/or lines) extend through the first dielectric layer 304. The conductive features 306 may couple with respective conductive features of the substrate 302. In various embodiments, the conductive features 306 comprise one or more metals such as tungsten (W), ruthenium (Ru), copper (Cu), tin (Sn), titanium (Ti), hafnium (Hf), silver (Ag), gold (Au), cobalt (Co), nickel (Ni), molybdenum (Mb), niobium (Nb), tantalum (Ta), rhodium (Rh), iridium (Ir), palladium (Pd), indium (In), zinc (Zn), antimony (Sb), the like, or a combination thereof.

A second dielectric layer 308 is formed over the first dielectric layer 304 and the conductive features 306. The second dielectric layer 308 may include similar materials as the first dielectric layer 304 (see above). The second dielectric layer 308 may be formed with direct liquid injection (DLI) or another suitable technique.

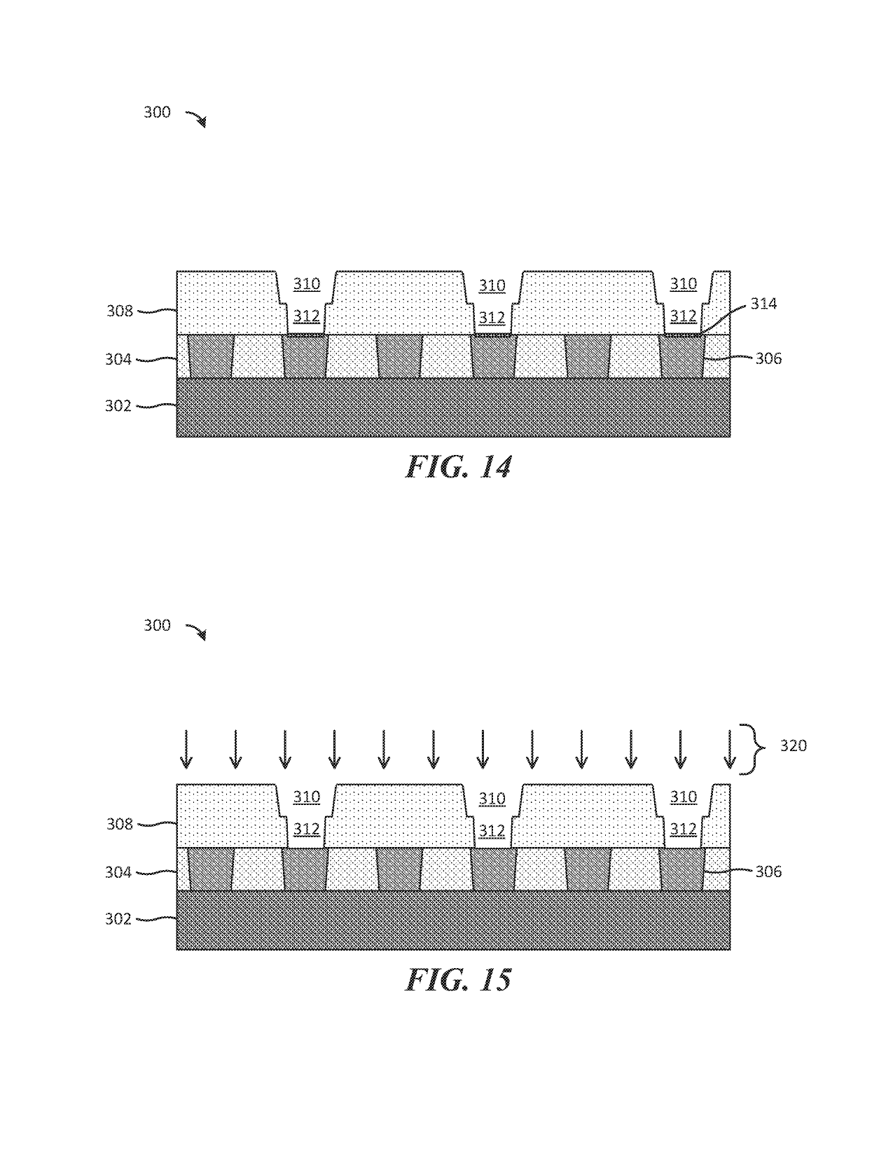

In FIG. 14, the second dielectric layer 308 is patterned (such as with an etching process) to form trenches 310 and holes 312. The trenches 310 are formed in the second dielectric layer 308 and the holes 312 are formed to extend from the trenches 310 to top surfaces of the conductive features 306. The trenches 310 and holes 312 may be formed with patterning and etching techniques from a conventional dual-damascene process, such as a via-first or a trench-first patterning sequence. In some embodiments, the etch process oxidizes exposed top surfaces of the conductive features 306 to form an oxide layer 314.

Next, in FIG. 15, a cleaning process 320 is performed to remove the oxide layer 314. In various embodiments, the cleaning process 320 comprises one or more cycles of an atomic layer etching (ALE) process including, for example, flowing a first precursor gas 210, performing a first purge 212, flowing a second precursor gas 214, and performing a second purge 216, as described above with respect to FIGS. 3-6. The cleaning process 320 may be performed for a suitable number of cycles until the oxide layer 314 is removed.

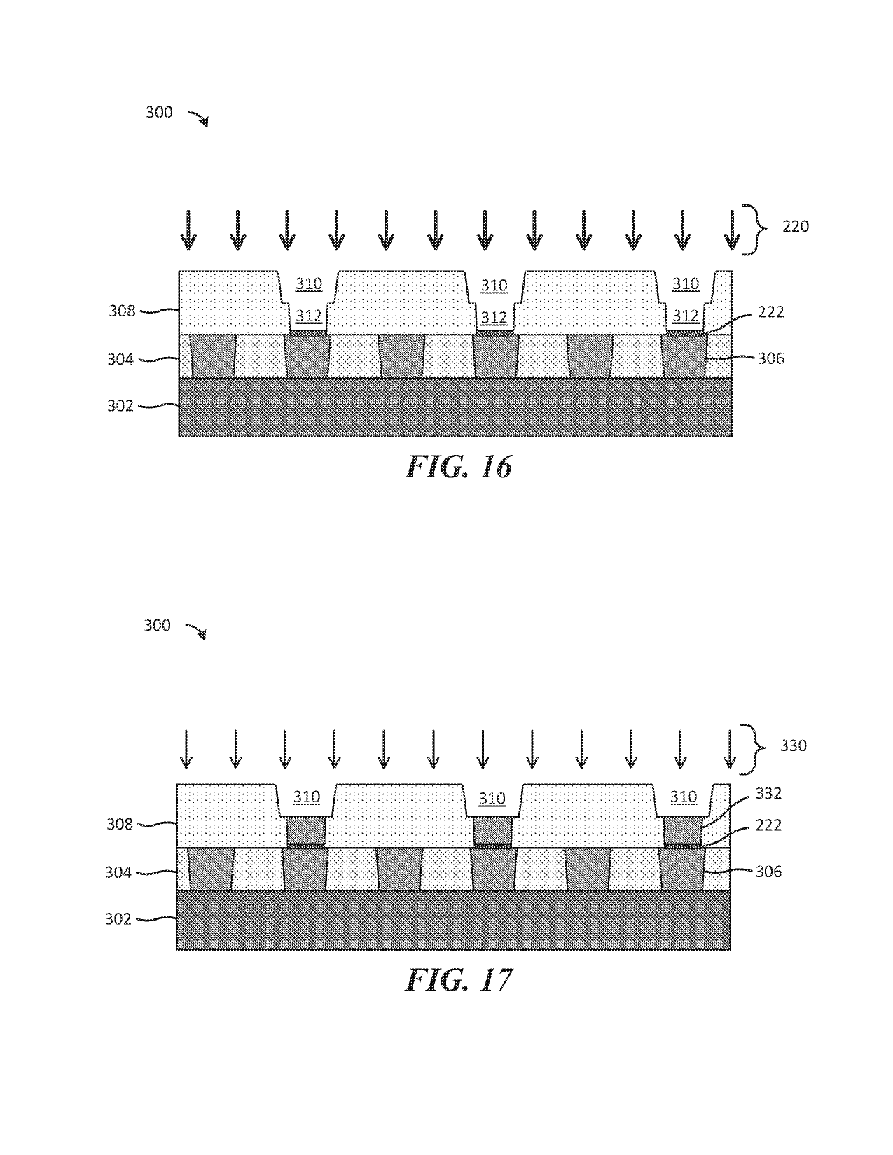

In FIG. 16, following from FIG. 15, a gallium layer 222 is formed over exposed top surfaces of the conductive features 306. The gallium layer 222 may be formed by flowing a gallium precursor 220 as described above with respect to FIG. 7, and the details are not repeated herein. The presence of the gallium layer 222 may promote the subsequent selective deposition of conductive material over the conductive features 306.

Next, in FIG. 17, conductive vias 332 are formed in the holes 312 with an atomic layer deposition (ALD) process 330 including, for example, one or more cycles of flowing a first precursor gas 230, performing a first purge 232, flowing a second precursor gas 234, and performing a second purge 236, as described above with respect to FIGS. 8-12. The conductive material (e.g., tungsten) is selectively deposited on the conductive features 306 rather than on the material of the second dielectric layer 308. In some embodiments, small amounts of conductive material are deposited on sidewalls of the second dielectric layer 308 above the conductive vias 332.

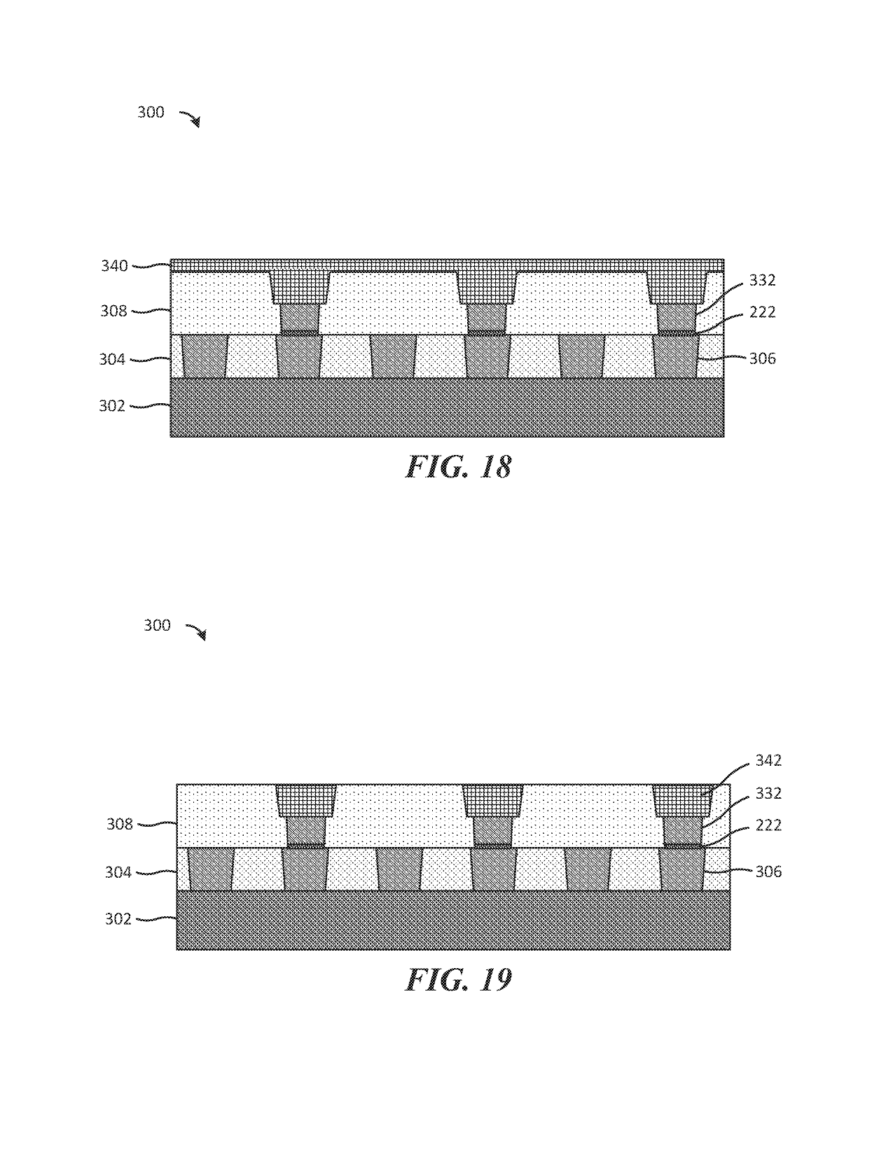

In FIG. 18, following from FIG. 17, a conductive fill material 340 is formed in the trenches 310 over the conductive vias 332 and over the second dielectric layer 308. In various embodiments, the conductive fill material 340 comprises a metal such as, for example, ruthenium (Ru), copper (Cu), tungsten (W), tin (Sn), titanium (Ti), hafnium (Hf), silver (Ag), gold (Au), cobalt (Co), nickel (Ni), molybdenum (Mb), niobium (Nb), tantalum (Ta), rhodium (Rh), iridium (Ir), palladium (Pd), indium (In), zinc (Zn), antimony (Sb), the like, or a combination thereof. The conductive fill material 340 may be formed with any suitable technique, such as electroplating, electroless plating, or the like.

Next, in FIG. 19, excess portions of the conductive fill material 340 are removed to form conductive lines 342. The excess portions of the conductive fill material 340 may be removed with a planarization technique such as, for example, a chemical mechanical polish (CMP). However, any suitable technique may be used to remove the excess portions of the conductive fill material 340. In some embodiments, a top portion of the second dielectric layer 308 over the conductive lines 342 is also removed.

FIG. 20 illustrates a process flow chart diagram of a method 800 for semiconductor manufacturing, in accordance with some embodiments. In step 802, an oxide layer disposed over a conductive feature is removed, as described above with respect to FIGS. 3-6. The conductive feature is adjacent to a dielectric feature. In step 804, a gallium precursor is flowed over the conductive feature, as described above with respect to FIG. 7. In step 806, after flowing the gallium precursor, a metal is deposited over the conductive feature, as described above with respect to FIGS. 8-12. The metal is deposited selectively over the conductive feature relative to the dielectric feature.

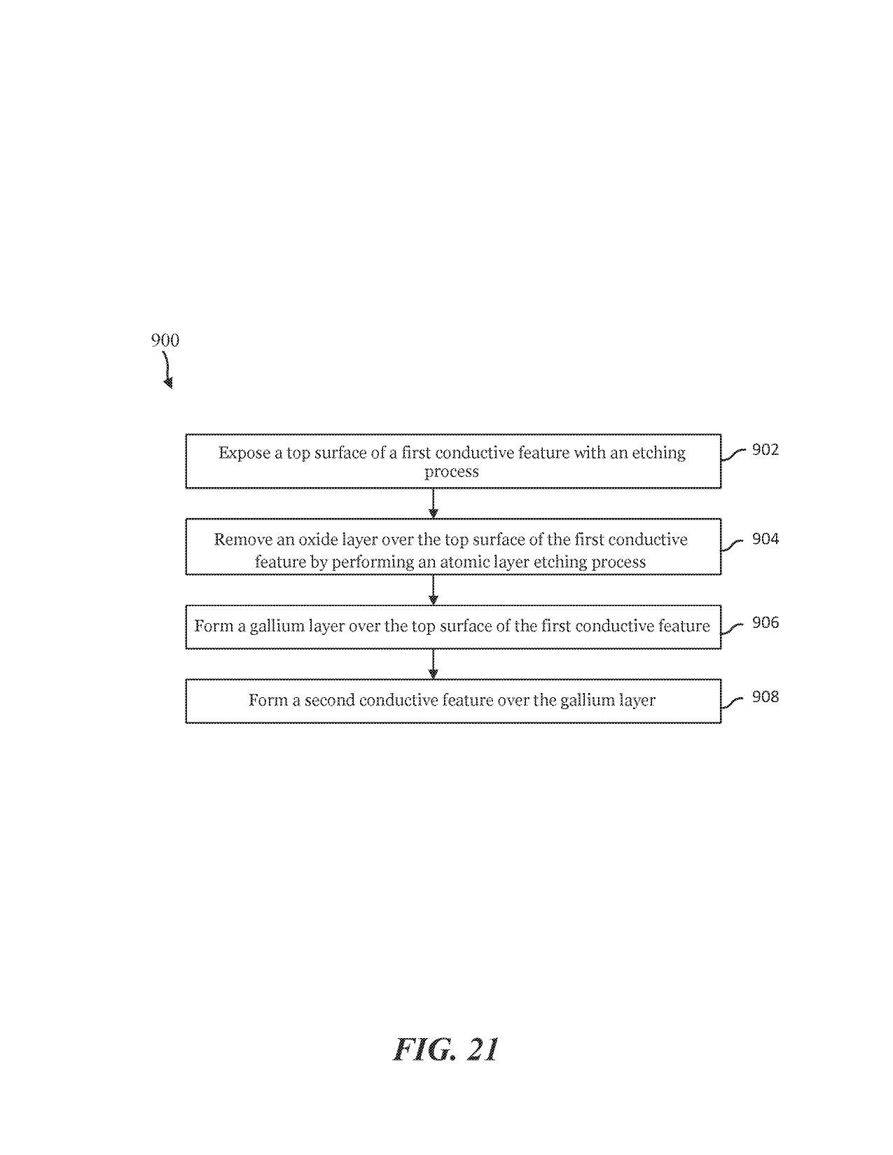

FIG. 21 illustrates a process flow chart diagram of a method 900 for semiconductor manufacturing, in accordance with some embodiments. In step 902, a top surface of a first conductive feature is exposed with an etching process, as described above with respect to FIGS. 2 and 14. The etching process forms an oxide layer over the top surface of the first conductive feature. In step 904, the oxide layer is removed by performing an atomic layer etching process, as described above with respect to FIGS. 3-6 and 15. In step 906, a gallium layer is formed over the top surface of the first conductive feature, as described above with respect to FIGS. 7 and 16. In step 908, a second conductive feature is formed over the gallium layer with an atomic layer deposition process, as described above with respect to FIGS. 8-12 and 17.

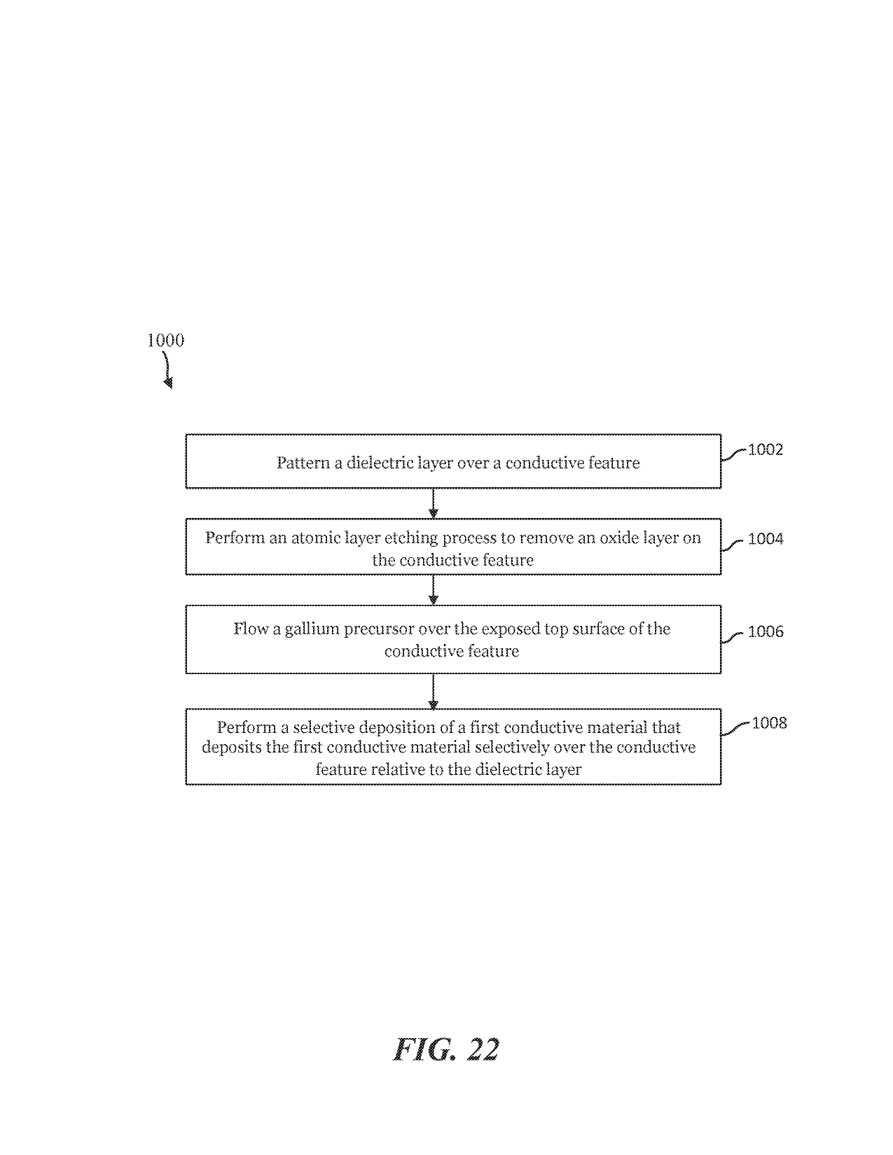

FIG. 22 illustrates a process flow chart diagram of a method 1000 for semiconductor manufacturing, in accordance with some embodiments. In step 1002, a dielectric layer is patterned over a conductive feature, as described above with respect to FIG. 14. The patterning forms a trench in the dielectric layer and a hole extending from the trench to a top surface of the conductive feature. In step 1004, an atomic layer etching process is performed, as described above with respect to FIG. 15. The atomic layer etching process removes an oxide layer on the conductive feature. In step 1006, a gallium precursor is flowed over the exposed top surface of the conductive feature, as described above with respect to FIG. 16. In step 1008, the hole is filled by performing a selective deposition of a first conductive material, as described above with respect to FIG. 17. The first conductive material is deposited selectively over the exposed top surface of the conductive feature relative to the dielectric layer.

Example embodiments of the disclosure are summarized here. Other embodiments can also be understood from the entirety of the specification as well as the claims filed herein.

Example 1. A method for semiconductor manufacturing, the method including: removing an oxide layer disposed over a conductive feature, the conductive feature being adjacent to a dielectric feature; flowing a gallium precursor over the conductive feature; and after flowing the gallium precursor, depositing a metal over the conductive feature, the metal being deposited selectively over the conductive feature relative to the dielectric feature.

Example 2. The method of example 1, where the metal includes tungsten.

Example 3. The method of example 2, where depositing the metal includes flowing a tungsten precursor and flowing a boron precursor.

Example 4. The method of example 3, where the tungsten precursor includes tungsten pentachloride, tungsten hexachloride, tungsten hexafluoride, or tungsten hexacarbonyl.

Example 5. The method of one of examples 3 or 4, where the boron precursor includes boron trifluoride, boron trichloride, or diborane.

Example 6. The method of one of examples 3 to 5, further including performing a purge with an inert gas between flowing the tungsten precursor and flowing the boron precursor.

Example 7. The method of example 6, where the inert gas includes argon, helium, or nitrogen.

Example 8. The method of one of examples 1 to 7, where the gallium precursor includes gallium(II) chloride, gallium trichloride, gallium(III) iodide, gallium(III) bromide, or gallium(III) fluoride.

Example 9. A method for semiconductor manufacturing, the method including: exposing a top surface of a first conductive feature with an etching process, the etching process forming an oxide layer over the top surface of the first conductive feature; removing the oxide layer by performing an atomic layer etching process; forming a gallium layer over the top surface of the first conductive feature; and forming a second conductive feature over the gallium layer with an atomic layer deposition process.

Example 10. The method of example 9, where the atomic layer etching process includes flowing a tungsten precursor and flowing a boron precursor.

Example 11. The method of example 10, where the flowing the tungsten precursor and the flowing the boron precursor are separated by a purge with an inert gas.

Example 12. The method of example 11, where the inert gas includes argon.

Example 13. The method of one of examples 11 or 12, where the atomic layer deposition process includes flowing the same tungsten precursor, flowing the same boron precursor, and purging with the same inert gas as the atomic layer etching process.

Example 14. The method of one of examples 9 to 13, where forming the gallium layer includes flowing gallium(II) chloride, gallium trichloride, gallium(III) iodide, gallium(III) bromide, or gallium(III) fluoride.

Example 15. A method for semiconductor manufacturing, the method including: patterning a dielectric layer over a conductive feature, the patterning forming a trench in the dielectric layer and a hole extending from the trench to a top surface of the conductive feature; performing an atomic layer etching process, the atomic layer etching process removing an oxide layer on the conductive feature; flowing a gallium precursor over the exposed top surface of the conductive feature; and filling the hole by performing a selective deposition of a first conductive material, the first conductive material being deposited selectively over the exposed top surface of the conductive feature relative to the dielectric layer.

Example 16. The method of example 15, where the conductive feature and the first conductive material include tungsten.

Example 17. The method of one of examples 15 or 16, further including filling the trench with a second conductive material, the second conductive material being different from the first conductive material.

Example 18. The method of example 17, where the second conductive material includes ruthenium.

Example 19. The method of one of examples 15 to 18, where the gallium precursor includes gallium(II) chloride, gallium trichloride, gallium(III) iodide, gallium(III) bromide, or gallium(III) fluoride.

Example 20. The method of one of examples 15 to 19, where the dielectric layer includes silicon dioxide.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for semiconductor manufacturing, the method comprising:
removing an oxide layer disposed over a conductive feature, the conductive feature being adjacent to a dielectric feature;
flowing a gallium precursor over the conductive feature; and
after flowing the gallium precursor, depositing a metal over the conductive feature, the metal being deposited selectively over the conductive feature relative to the dielectric feature.

2. The method of claim 1, wherein the metal comprises tungsten.

3. The method of claim 2, wherein depositing the metal comprises flowing a tungsten precursor and flowing a boron precursor.

4. The method of claim 3, wherein the tungsten precursor comprises tungsten pentachloride, tungsten hexachloride, tungsten hexafluoride, or tungsten hexacarbonyl.

5. The method of claim 3, wherein the boron precursor comprises boron trifluoride, boron trichloride, or diborane.

6. The method of claim 3, further comprising performing a purge with an inert gas between flowing the tungsten precursor and flowing the boron precursor.

7. The method of claim 6, wherein the inert gas comprises argon, helium, or nitrogen.

8. The method of claim 1, wherein the gallium precursor comprises gallium(II) chloride, gallium trichloride, gallium(III) iodide, gallium(III) bromide, or gallium(III) fluoride.

9. A method for semiconductor manufacturing, the method comprising:
exposing a top surface of a first conductive feature with an etching process, the etching process forming an oxide layer over the top surface of the first conductive feature;
removing the oxide layer by performing an atomic layer etching process;
forming a gallium layer over the top surface of the first conductive feature; and
forming a second conductive feature over the gallium layer with an atomic layer deposition process.

10. The method of claim 9, wherein the atomic layer etching process comprises flowing a tungsten precursor and flowing a boron precursor.

11. The method of claim 10, wherein the flowing the tungsten precursor and the flowing the boron precursor are separated by a purge with an inert gas.

12. The method of claim 11, wherein the inert gas comprises argon.

13. The method of claim 11, wherein the atomic layer deposition process comprises flowing the same tungsten precursor, flowing the same boron precursor, and purging with the same inert gas as the atomic layer etching process.

14. The method of claim 9, wherein forming the gallium layer comprises flowing gallium(II) chloride, gallium trichloride, gallium(III) iodide, gallium(III) bromide, or gallium(III) fluoride.

15. A method for semiconductor manufacturing, the method comprising:
patterning a dielectric layer over a conductive feature, the patterning forming a trench in the dielectric layer and a hole extending from the trench to a top surface of the conductive feature;
performing an atomic layer etching process, the atomic layer etching process removing an oxide layer on the conductive feature;
flowing a gallium precursor over the exposed top surface of the conductive feature; and
filling the hole by performing a selective deposition of a first conductive material, the first conductive material being deposited selectively over the exposed top surface of the conductive feature relative to the dielectric layer.

16. The method of claim 15, wherein the conductive feature and the first conductive material comprise tungsten.

17. The method of claim 15, further comprising filling the trench with a second conductive material, the second conductive material being different from the first conductive material.

18. The method of claim 17, wherein the second conductive material comprises ruthenium.

19. The method of claim 15, wherein the gallium precursor comprises gallium(II) chloride, gallium trichloride, gallium(III) iodide, gallium(III) bromide, or gallium(III) fluoride.

20. The method of claim 15, wherein the dielectric layer comprises silicon dioxide.
